(19) United States
(12) Patent Application Publication
(10) Pub. No.: US 2024/0113028 A1
(43) Pub. Date: Apr. 4, 2024

(54) INTERCONNECTION LAYER STRUCTURES INCLUDING TWO-DIMENSIONAL (2D) MATERIAL, ELECTRONIC DEVICES INCLUDING INTERCONNECTION LAYER STRUCTURES, AND ELECTRONIC APPARATUSES INCLUDING ELECTRONIC DEVICES

(71) Applicants: Samsung Electronics Co., Ltd., Suwon-si (KR); President and Fellows Of Harvard College, Cambridge, MA (US)

(72) Inventors: Yeonchoo CHO, Suwon-si (KR); Elise BRUTSCHEA, Cambridge, MA (US); Hongkun PARK, Cambridge, MA (US); Minsu SEOL, Suwon-si (KR)

(73) Assignees: Samsung Electronics Co., Ltd., Suwon-si (KR); President and Fellows Of Harvard College, Cambridge, MA (US)

(21) Appl. No.: 18/471,715

(22) Filed: Sep. 21, 2023

Related U.S. Application Data
(60) Provisional application No. 63/411,256, filed on Sep. 29, 2022.

(30) Foreign Application Priority Data
Nov. 8, 2022 (KR) 10-2022-0148135

(51) Int. Cl. H01L 23/532; H01L 23/528; H01L 29/45; H01L 29/49

(52) U.S. Cl. CPC H01L 23/53266; H01L 23/5283; H01L 23/53223; H01L 23/53252; H01L 29/45; H01L 29/4908

(57) ABSTRACT

An interconnection layer structure including a two-dimensional (2D) material, an electronic device including the interconnection layer structure, and an electronic apparatus including the electronic device are disclosed. The interconnection layer structure may include a first interconnection layer, and a work function modulation layer directly on one surface of the first interconnection layer. The first interconnection layer may include a metal layer, and the work function modulation layer may be a two-dimensional (2D) material layer that includes ruthenium (Ru).

### CROSS-REFERENCE TO RELATED APPLICATIONS

This application is based on and claims priority under 35 U.S.C. § 119 to U.S. Provisional Application No. 63/411,256, filed on Sep. 29, 2022, in the US Patent Office and Korean Patent Application No. 10-2022-0148135, filed on Nov. 8, 2022, in the Korean Intellectual Property Office, the disclosures of which are incorporated by reference herein in their entireties.

### BACKGROUND

### 1. Field

The present disclosure relates to an interconnection layer structure and an application thereof, and more particularly, to interconnection layer structures including a two-dimensional (2D) material, electronic devices including the interconnection layer structures, and electronic apparatuses including the electronic devices.

### 2. Description of Related Art

Increasing a doping density of a semiconductor layer is one of the methods of forming an ohmic contact between a metal layer and the semiconductor layer. That is, this method results in an excessive doping of the semiconductor layer. In the case of a two-dimensional (2D) semiconductor layer, the excessive doping may be difficult.

Lowering the Schottky barrier is another way of forming an ohmic contact, but this method may be difficult due to a phenomenon known as Fermi-level pinning.

### SUMMARY

Provided are interconnection layer structures capable of forming an ohmic contact between a metal layer and a semiconductor layer.

Provided are electronic devices including the interconnection layer structures.

Provided are electronic apparatuses including the electronic devices.

Additional aspects will be set forth in part in the description which follows and, in part, will be apparent from the description, or may be learned by practice of the presented embodiments of the disclosure.

According to an embodiment, an interconnection layer structure may include a first interconnection layer, and a work function modulation layer directly on one surface of the first interconnection layer. The first interconnection layer may include a metal layer, and the work function modulation layer may be a two-dimensional (2D) material layer that includes ruthenium (Ru).

In some embodiments, the interconnection layer structure may further include a second interconnection layer facing the first interconnection layer with the work function modulation layer therebetween. The second interconnection layer may directly contact the work function modulation layer. In some embodiments, the second interconnection layer may include a semiconductor layer.

In some embodiments, the interconnection layer structure may further include an insulating layer. The first interconnection layer, the work function modulation layer, and the second interconnection layer may be stacked in a horizontal direction on one surface of the insulating layer.

In some embodiments, a portion of the first interconnection layer and the second interconnection layer may overlap each other.

In some embodiments, the interconnection layer structure may further include an insulating layer. The first interconnection layer, the work function modulation layer, and the second interconnection layer may be vertically stacked on the insulating layer.

In some embodiments, one of the first interconnection layer and the second interconnection layer may include a trench. The work function modulation layer may cover a side surface of the trench and a bottom surface of the trench. A rest of the trench may be filled with an other of the first interconnection layer and the second interconnection layer.

In some embodiments, the interconnection layer structure may further include an interlayer insulating layer between the first interconnection layer and the second interconnection layer. The interlayer insulating layer may include a through hole in fluid communication with the trench.

In some embodiments, the work function modulation layer may extend onto the interlayer insulating layer around the trench.

In some embodiments, one of the first interconnection layer and the second interconnection layer may include a protruding portion. The work function modulation layer may cover the protruding portion. An other of the first interconnection layer and the second interconnection layer may cover the protruding portion with the work function modulation layer therebetween.

In some embodiments, the interconnection layer structure may further include an interlayer insulating layer between the first interconnection layer and the second interconnection layer. The interlayer insulating layer may surround the protruding portion.

In some embodiments, the work function modulation layer may extend onto the interlayer insulating layer around the protruding portion.

In some embodiments, the first interconnection layer may include a trench, and the work function modulation layer may be in the trench.

In some embodiments, the first interconnection layer may include a protruding portion, and the protruding portion may be covered with the work function modulation layer.

According to an embodiment, an electronic device may include a substrate, a 2D semiconductor channel layer on the substrate, a first electrode layer connected to a first side region of the 2D semiconductor channel layer, a second electrode layer connected to a second side region of the 2D semiconductor channel layer and spaced apart from the first electrode layer, a third electrode layer on the 2D semiconductor channel layer, and a first work function modulation layer between the 2D semiconductor channel layer and each of the first electrode layer and the second electrode layer. The third electrode layer may be spaced apart from the first electrode layer and the second electrode layer. The first work function modulation layer may directly contact the first electrode layer. The first work function modulation layer may directly contact the second electrode layer. The first work function modulation layer may include ruthenium (Ru).

According to an embodiment, a memory device may include a switching device and a data storage element coupled to the switching device. The switching device may include the electronic device described above.

According to an embodiment, an electronic apparatus may include the electronic device and the memory device described above.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 to 18B are cross-sectional views or plan views illustrating various interconnection layer structures including a work function modulation layer according to embodiments;

FIG. 19A is a cross-sectional view illustrating an electronic device according to an embodiment;

FIG. 19B is a cross-sectional view illustrating an electronic device according to an embodiment;

FIG. 20 is a cross-sectional view illustrating an electronic device according to an embodiment;

FIG. 21 is a three-dimensional (3D) view illustrating an electronic device according to an embodiment;

FIG. 22 is a cross-sectional view illustrating an electronic device according to an embodiment;

FIG. 23 is a schematic block diagram of a display driver IC (DDI) and a display device including the DDI according to an embodiment;

FIG. 24 is a block diagram illustrating an electronic system according to an embodiment;

FIG. 25 is a block diagram of an electronic system according to an embodiment; and

FIG. 26 is a block diagram showing a schematic configuration of an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of a, b, and c” may be understood to include “only a,” “only b,” “only c,” “a and b,” “a and c,” “b and c,” or “a, b, and c”.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, interconnection layer structures including a two-dimensional (2D) channel layer, electronic devices including the interconnection layer structures, and electronic apparatuses including the electronic devices will be described in detail with reference to the accompanying drawings.

In the drawings, thicknesses of layers and regions may be exaggerated for clarification of the specification. The embodiments of the disclosure are capable of various modifications and may be embodied in many different forms. When an element or layer is referred to as being “on” or “above” another element or layer, the element or layer may be directly on another element or layer or intervening elements or layers. In the following descriptions, like reference numerals refer to like elements.

Also, in the following description, “interconnection” or “interconnection layer” is not an insulating layer, but a layer having electrical conductivity through which electrons or holes may move, may be a conductive material layer including a metal or include such a material layer, or may be a semiconductor layer prepared to have conductivity or include such a semiconductor layer.

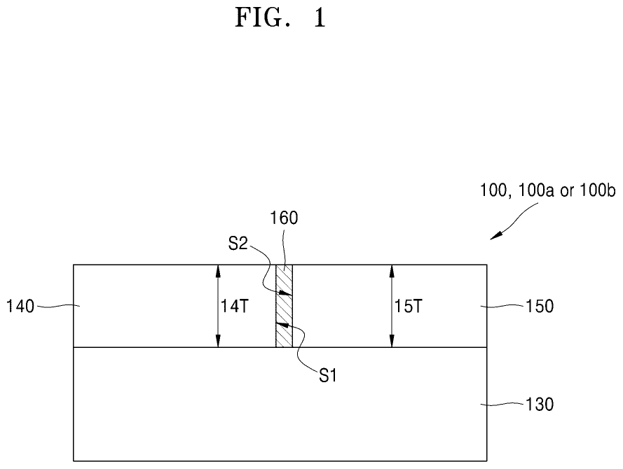

First, interconnection layer structures including a work function modulation layer according to embodiments will be described with reference to FIGS. 1 to 18B.

FIG. 1 shows an interconnection layer structure 100 (or 100a or 100b), including a work function modulation layer according to an embodiment.

Referring to FIG. 1, the interconnection layer structure 100 (or 100a or 100b) includes a first interconnection layer 140 and a second interconnection layer 150 provided on an insulating layer 130 and a work function modulation layer 160 disposed between the first and second interconnection layers 140 and 150. The first interconnection layer 140 and the second interconnection layer 150 are spaced apart from each other and do not directly contact each other. The first interconnection layer 140 and the second interconnection layer 150 are indirectly in contact with each other through the work function modulation layer 160. The first interconnection layer 140, the second interconnection layer 150, and the work function modulation layer 160 may be formed on the same surface (e.g., upper surface) of the insulating layer 130, and the first and second interconnection layers 140 and 150 are horizontally spaced apart from each other, but are not limited thereto. In some embodiments, the first and second interconnection layers 140 and 150 may be provided on different surfaces of the insulating layer 130. In some embodiments, a first thickness 14T of the first interconnection layer 140 and a second thickness 15T of the second interconnection layer 150 may be the same as or different from each other. In some embodiments, the second thickness 15T of the second interconnection layer 150 may be greater than the first thickness 14T of the first interconnection layer 140 or vice versa. In some embodiments, the insulating layer 130 may include two surfaces having different heights, and the first interconnection layer 140 and the second interconnection layer 150 may be in indirect contact with each other through the work function modulation layer 160 and may face each other in a state that the first interconnection layer 140 and the second interconnection layer 150 are respectively formed on the two surfaces of the insulating layer 130 having different heights.

In some embodiments, one of the first interconnection layer 140 and the second interconnection layer 150 may be a material layer including a metal, and the other may be a material layer including a semiconductor as a non-metal layer. In some embodiments, the material layer including a metal may be or include a metal layer. In some embodiments, the material layer including a metal may be an alloy layer including different metals or include such an alloy layer. In some embodiments, the metal may include at least one of Al, Ti, Co, Ni, Cu, Zn, Mo, Ru, Rh, Pd, Ag, W, Ir, Pt, Au, Bi, and Sb. In some embodiments, the alloy may include a binary alloy, a ternary alloy, or a silicide.

In some embodiments, the material layer including the semiconductor may be a semiconductor layer or include the semiconductor layer. In some embodiments, the semiconductor layer may be a compound semiconductor layer or include the compound semiconductor layer. In some embodiments, the semiconductor layer may include a semiconductor layer doped with a p-type or an n-type conductive impurity. In some embodiments, the compound semiconductor layer may be a Group III-V compound semiconductor layer, but is not limited thereto. In some embodiments, the material layer including a metal may have a first work function. In some embodiments, a band gap of the material layer including the semiconductor may be 0.1 electron volt (eV) or more, but may not be limited to this value.

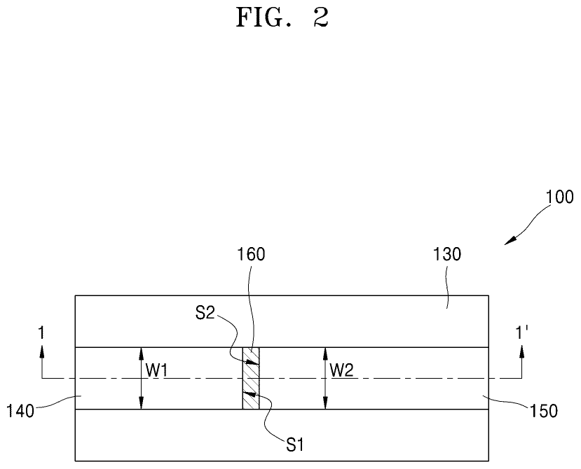

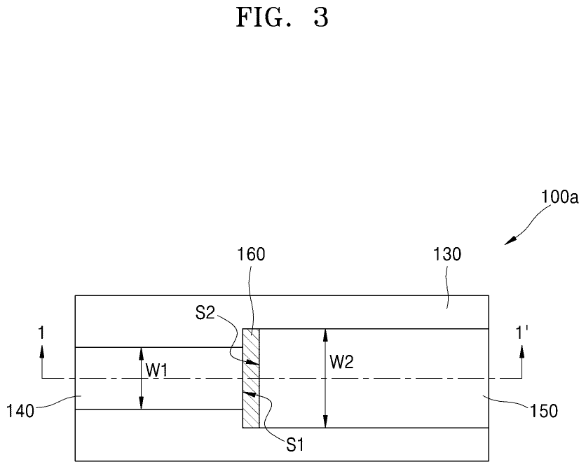

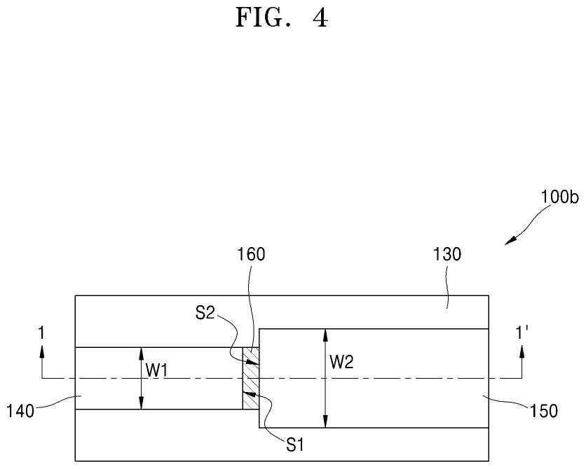

In some embodiments, a first surface S1 of the first interconnection layer 140 and a second surface S2 of the second interconnection layer 150 that are in direct contact with the work function modulation layer 160 may directly face each other with the work function modulation layer 160 therebetween. When the work function modulation layer 160 is not provided, the first surface S1 of the first interconnection layer 140 and the second surface S2 of the second interconnection layer 150 may directly contact each other. When the work function modulation layer 160 is not provided, the entire first surface 51 may directly contact the entire second surface S2. When the work function modulation layer 160 is provided, the entire first surface S1 of the first interconnection layer 140 may be covered with the work function modulation layer 160, and the entire second surface S2 of the second interconnection layer 150 may also be covered with the work function modulation layer 160. In some embodiments, an area of the surfaces of the first and second interconnection layers 140 and 150 facing each other may be the same as or different from each other. For example, as shown in the interconnection layer structure 100 of FIG. 2, which is an example of the plan view of FIG. 1, a first width W1 of the first interconnection layer 140 and a second width W2 of the second interconnection layer 150 may be the same. In some embodiments, as shown in FIG. 3, which is another example of the plan view of FIG. 1, the first width W1 of the first interconnection layer 140 may be less than the second width W2 of the second interconnection layer 150, and vice versa.

In other words, FIGS. 1 and 2 show an embodiment of an interconnection layer structure 100 in which the area of the first surface S1 of the first interconnection layer 140 contacting the work function modulation layer 160 and the area of the second surface S2 of the second interconnection layer 150 contacting the work function modulation layer 160 are the same.

FIGS. 1 and 3 show an embodiment of an interconnection layer structure 100a in which the area of the first surface S1 of the first interconnection layer 140 contacting the work function modulation layer 160 and the area of the second surface S2 of the second interconnection layer 150 contacting the work function modulation layer 160 are different from each other. In the interconnection layer structures 100 and 100a of FIGS. 1 to 3, one of the first and second interconnection layers 140 and 150 may include a metal layer, and the other may include an n-type or p-type semiconductor layer. For example, as shown in FIG. 3, a width W2 of the second interconnection layer 150 may be greater than a width W1 of the first interconnection layer 140 and a width of the work function modulation layer 150 may be equal to W2 of the second interconnection layer 150.

In some embodiments, when the widths of the first and second interconnection layers 140 and 150 are different from each other, FIGS. 1 and 4 show an embodiment of an interconnection layer structure 100b in which only a partial area corresponding to the first surface S1 of the first interconnection layer 140 among the second surface S2 of the second interconnection layer 150 having a width greater than that of the first interconnection layer 140 is covered with the work function modulation layer 160 while the entire area of the first surface S1 of the first interconnection layer 140 is covered with the work function modulation layer 160. In the embodiments illustrated in FIGS. 1 and 4, the first interconnection layer 140 may include a metal layer, and the second interconnection layer 150 may include a semiconductor layer. In FIG. 4, the width of the work function modulation layer 160 may be equal to W1 of the first interconnection layer 140. The width W2 of the second interconnection layer 150 may be greater than the width W1 of the first interconnection layer 140.

In the plan views of FIGS. 2 to 4, the first and second interconnection layers 140 and 150 and the work function modulation layer 160 may be surrounded by an interlayer insulating layer.

FIG. 1 shows a cross-section of FIG. 2 cut in a 1-1′ direction, a cross-section of FIG. 3 cut in the 1-1′ direction, or a cross-section of FIG. 4 cut in the 1-1′ direction.

The work function modulation layer 160 is present between the contact surfaces of the first and second interconnection layers 140 and 150, and an interconnection layer used as a metal interconnection layer among the first and second interconnection layers 140 and 150, for example, the first surface S1 of the first interconnection layer 140 is covered with the work function modulation layer 160 and is in direct contact with the work function modulation layer 160. The work function modulation layer 160 may be or may include a 2D material layer that changes a surface characteristic or surface structure of the first surface S1 of the first interconnection layer 140. Accordingly, the work function of the first interconnection layer 140 increases from a first work function to a second work function. That is, the work function of the first interconnection layer 140 is increased when the first surface S1 of the first interconnection layer 140 is covered with the work function modulation layer 160 than when the first surface S1 is not covered with the work function modulation layer 160. In this regard, the work function modulation layer 160 may be variously expressed as a material layer increasing a work function, a work function increasing layer, or a work function changing layer.

As the first surface S1 of the first interconnection layer 140 is covered with the work function modulation layer 160, which is a 2D material, the work function of the first interconnection layer 140 is increased and the Fermi level pinning of the first interconnection layer 140 may be minimized or attenuated. Accordingly, the Schottky barrier between the first interconnection layer 140 and the second interconnection layer 150 may be lowered, and thus, an ohmic contact between the first interconnection layer 140 and the second interconnection layer 150 may be formed.

Although the case when the first interconnection layer 140 is a metal interconnection layer and the second interconnection layer 150 is a semiconductor interconnection layer has been described as an example, the opposite case is also the same. In other words, the first interconnection layer 140 may be a semiconductor interconnection layer and the second interconnection layer 150 may be metal interconnection layer.

In some embodiments, the 2D material of the work function modulation layer 160 may include RuCl, transition metal dichalcogenide (TMD), or MXene. In some embodiments, when the 2D material layer includes a RuCl layer, the 2D material layer may include an alpha phase RuCl3 (α-RuCl3) layer, but is not limited thereto. In some embodiments, the TMD may include a Janus type TMD (Janus TMD).

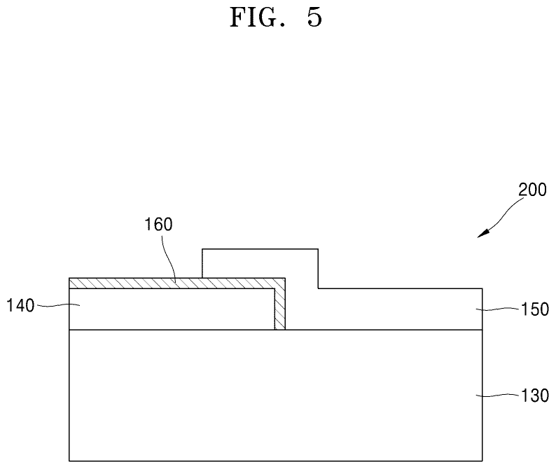

FIG. 5 is a cross-sectional view illustrating an interconnection layer structure 200 according to an embodiment. Only parts different from the interconnection layer structure 100, 100a, and 100b are described.

Referring to FIG. 5, first and second interconnection layers 140 and 150 are provided on an insulating layer 130, and a portion of the second interconnection layer 150 extends onto the first interconnection layer 140. That is, a part of the second interconnection layer 150 covers one end of the first interconnection layer 140. In other words, a portion of the first interconnection layer 140 extends below the second interconnection layer 150. The arrangement relationship of the first and second interconnection layers 140 and 150 may be opposite to each other. At the overlapping portion of the first and second interconnection layers 140 and 150, the first and second interconnection layers 140 and 150 do not directly contact each other, and a work function modulation layer 160 is provided between the first and second interconnection layers 140 and 150. The work function modulation layer 160 may be provided to cover the entire contact surface where the first interconnection layer 140 and the second interconnection layer 150 come into contact with each other when the work function modulation layer 160 is not provided. For example, the work function modulation layer 160 may be provided to cover a side surface of the first interconnection layer 140 facing the second interconnection layer 150 and also to cover a portion of an upper surface of the first interconnection layer 140 adjacent to the side surface thereof. The work function modulation layer 160 may be provided to completely cover surfaces (e.g., a side surface, an upper surface, and a bottom surface) of the first and second interconnection layers 140 and 150 facing each other between the first and second interconnection layers 140 and 150. The work function modulation layer 160 may cover the entire upper surface of the first interconnection layer 140. The second interconnection layer 150 may cover an entire side surface of the work function modulation layer 160 covering the side surface of the first interconnection layer 140. A portion of the second interconnection layer 150 may extend onto an upper surface of the work function modulation layer 160.

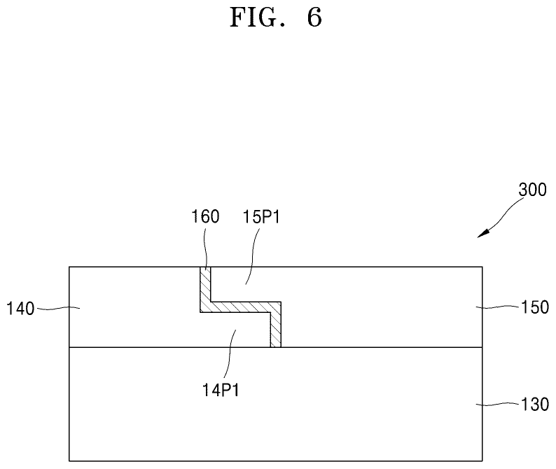

FIG. 6 shows an interconnection layer structure 300 according to an embodiment.

Referring to FIG. 6, in the interconnection layer structure 300, first and second interconnection layers 140 and 150 are formed horizontally on an insulating layer 130 and have the same thickness as each other.

A right end of the first interconnection layer 140 has a step difference. A left end of the second interconnection layer 150 corresponding to the right end of the first interconnection layer 140 also has a step difference. The first and second interconnection layers 140 and 150 are connected to each other through the step difference. A work function modulation layer 160 directly contacting both sides of the first and second interconnection layers 140 and 150 is formed between the step difference of the first interconnection layer 140 and the step difference of the second interconnection layer 150. As a result, the first and second interconnection layers 140 and 150 are indirectly connected to each other horizontally through the work function modulation layer 160.

A shape of the step difference of the first interconnection layer 140 may be opposite to that of the second interconnection layer 150. For example, when the first interconnection layer 140 is divided into an upper layer and a lower layer and the second interconnection layer 150 is also divided into an upper layer and a lower layer, the lower layer of the first interconnection layer 140 protrudes to the right with a first length, and the upper layer of the second interconnection layer 150 protrudes to the left with the same length. At the portion where the first and second interconnection layers 140 and 150 are connected to each other, a protruding portion 14P1 of the lower layer of the first interconnection layer 140 and a protruding portion 15P1 of the upper layer of the second interconnection layer 150 overlap each other. That is, the protruding portion 15P1 of the upper layer of the second interconnection layer 150 is positioned on the protruding portion 14P1 of the lower layer of the first interconnection layer 140. The work function modulation layer 160 may completely fill between the protruding portions 14P1 and 15P1.

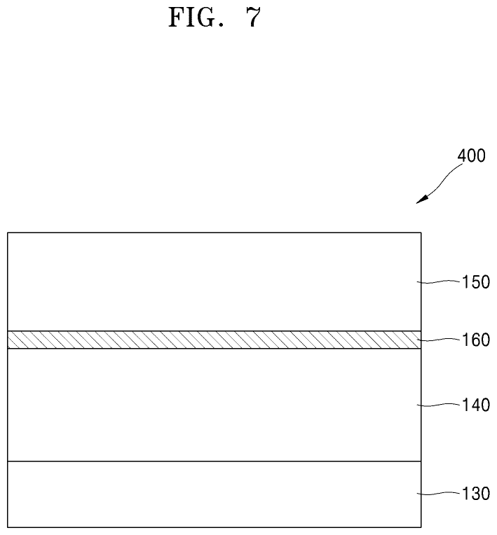

FIG. 7 shows an interconnection layer structure 400 according to an embodiment. In the interconnection layer structure 400, the first and second interconnection layers 140 and 150 are vertically connected through a work function modulation layer 160.

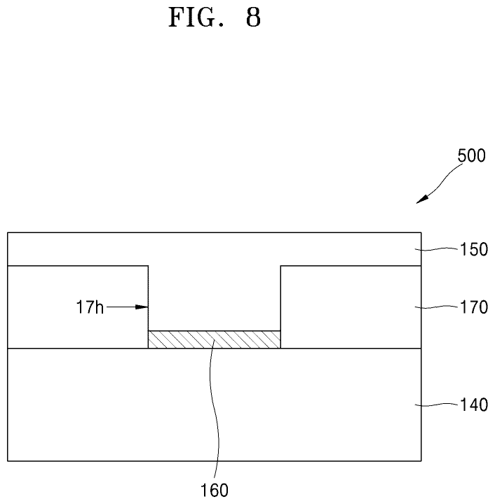

Specifically, referring to FIG. 7, the first interconnection layer 140, the work function modulation layer 160, and the second interconnection layer 150 are sequentially stacked. The work function modulation layer 160 may directly contact an upper surface of the first interconnection layer 140 and cover the entire upper surface thereof. In addition, the work function modulation layer 160 may directly contact a surface of the second interconnection layer 150 facing an upper surface of the first interconnection layer 140, that is, a lower surface of the second interconnection layer 150, and may cover the entire lower surface. The first interconnection layer 140 may be on an insulating layer 130 or the insulating layer 130 may be omitted. Similarly, although not shown in FIGS. 8 to 17 discussed below, the first interconnection layer 140 may be on an insulating layer 130.

FIG. 8 shows an interconnection layer structure 500 according to an embodiment. Like the interconnection layer structure 400, the interconnection layer structure 500 is a structure in which first and second interconnection layers 140 and 150 are vertically connected through a work function modulation layer 160.

Referring to FIG. 8, an interlayer insulating layer 170 is formed on the first interconnection layer 140, and a through hole 17h is formed in the interlayer insulating layer 170. The through hole 17h may also be expressed as a via hole. A portion of one surface (e.g., upper surface) of the first interconnection layer 140 is exposed through the through hole 17h. The work function modulation layer 160 is formed on an exposed surface of the one surface of the first interconnection layer 140. The entire exposed surface of the first interconnection layer 140 may be covered with the work function modulation layer 160 and may directly contact the work function modulation layer 160. In some embodiments, the work function modulation layer 160 may be a 2D monolayer or may have a layer structure in which a plurality of 2D monolayers are stacked. The layer structure of the work function modulation layer 160 may also be applied to the interconnection layer structures described above. The work function modulation layer 160 may cover only the exposed surface of the first interconnection layer 140, and the through hole 17h may not be filled with the work function modulation layer 160. A second interconnection layer 150 is formed on the interlayer insulating layer 170. The second interconnection layer 150 may be provided to fill the rest of the through hole 17h that is partially filled with the work function modulation layer 160. That is, the rest of the through hole 17h partially filled with the work function modulation layer 160 may be completely filled with the second interconnection layer 150. The second interconnection layer 150 directly contacts the work function modulation layer 160. An entire lower surface of the second interconnection layer 150 facing the exposed surface of the first interconnection layer 140 within the through hole 17h is covered with the work function modulation layer 160, and is in direct contact with the work function modulation layer 160. In this way, an upper surface of the second interconnection layer 150 filling the through hole 17h may be flat.

In some embodiments, the second interconnection layer 150 may fill only the through hole 17h without extending onto the interlayer insulating layer 170, and another material layer may be formed on the upper surface of the interlayer insulating layer 170 to cover the through hole 17h. In this case, the another material layer may have material characteristics identical to or similar to those of the second interconnection layer 150. For example, when the second interconnection layer 150 is a metal layer, the another material layer may be a metal layer or an alloy layer, and when the second interconnection layer 150 is a semiconductor layer, the another material layer may also be a semiconductor layer.

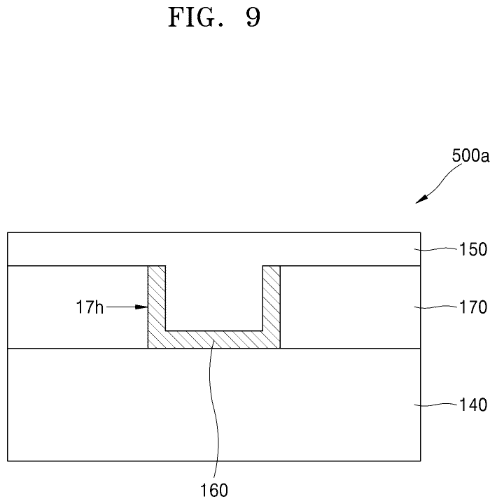

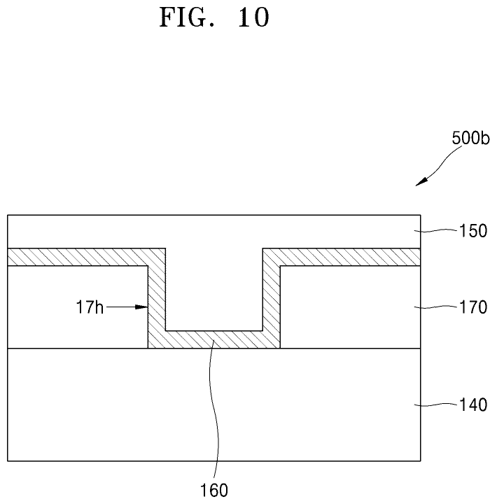

In some embodiments, as shown in the interconnection layer structure 500a of FIG. 9, the work function modulation layer 160 may extend between a side surface of the through hole 17h and the second interconnection layer 150 within the through hole 17h. That is, both the surface of the first interconnection layer 140 exposed through the through hole 17h and the side surface of the through hole 17h may be covered with the work function modulation layer 160, and the second interconnection layer 150 may be provided in the form of filling the through hole 17h.

In some embodiments, as shown in the interconnection layer structure 500b of FIG. 10, the interconnection layer structure 500b may be like the interconnection layer structure 500a in FIG. 9, except the work function modulation layer 160 may extend onto the interlayer insulating layer 170 around the through hole 17h. In some embodiments, the work function modulation layer 160 may cover the entire upper surface of the interlayer insulating layer 170 around the through hole 17h.

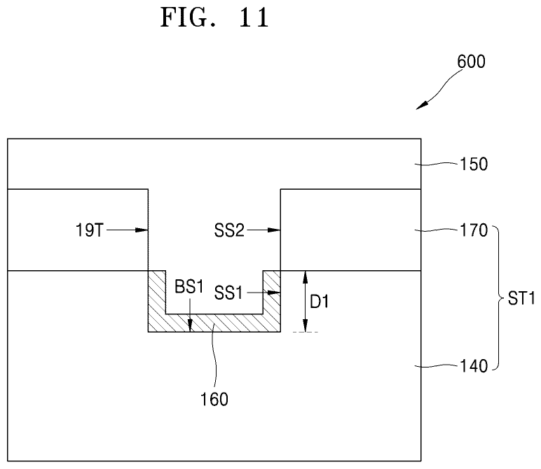

FIGS. 11 to 13 show interconnection layer structures 600, 600a, and 600b according to some embodiments. The interconnection layer structure 600 is also a structure in which first and second interconnection layers 140 and 150 are vertically connected through a work function modulation layer 160. The interconnection layer structures 600, 600a, and 600b illustrated in FIGS. 11 to 13 may be seen as embodiments in which the through hole 17h extends to the first interconnection layer 140 to a first depth D1 in the interconnection layer structures shown in FIGS. 8 to 10.

Specifically, referring to the interconnection layer structure 600 in FIG. 11, the interlayer insulating layer 170 is formed on the first interconnection layer 140. A first trench 19T is formed in a first stack ST1 including the sequentially stacked first interconnection layer 140 and the interlayer insulating layer 170. The first trench 19T penetrates the interlayer insulating layer 170 and extends to the first interconnection layer 140 to the first depth D1. The first trench 19T may be regarded as a result that, in FIG. 8, the through hole 17h is extended into the first interconnection layer 140.

The first interconnection layer 140 and the interlayer insulating layer 170 are exposed through the first trench 19T. In a portion of the first interconnection layer 140 exposed through the first trench 19T, a surface BS1 at the first depth D1 is parallel to an upper surface of the first interconnection layer 140 but is a bottom surface of the first trench 19T. A surface perpendicular to the upper surface of the first interconnection layer 140, that is, a first side surface SS1 perpendicular to a bottom surface BS1 of the first trench 19T forms a side surface SS1+SS2 of the first trench 19T together with an exposed second surface SS2 of the interlayer insulating layer 170.

The bottom surface BS1 and the first side surface SS1 of the first trench 19T are covered with the work function modulation layer 160. The work function modulation layer 160 is formed as a single layer or multiple layers along the bottom surface BS1 and the first side surface SS1 of the first trench 19T. A region of the first trench 19T surrounded by the first interconnection layer 140 or a portion of the first trench 19T formed on the first interconnection layer 140 may not be completely filled with the work function modulation layer 160. The rest region of the first trench 19T on which the work function modulation layer 160 is formed may be completely filled with the second interconnection layer 150. The second interconnection layer 150 may extend onto the upper surface of the interlayer insulating layer 170.

In some embodiments, the second interconnection layer 150 may be provided to completely fill only the first trench 19T. In this case, another material layer having the same or similar material characteristics as the second interconnection layer 150 may be provided on the upper surface of the interlayer insulating layer 170 to cover the first trench 19T and come in contact with the second interconnection layer 150.

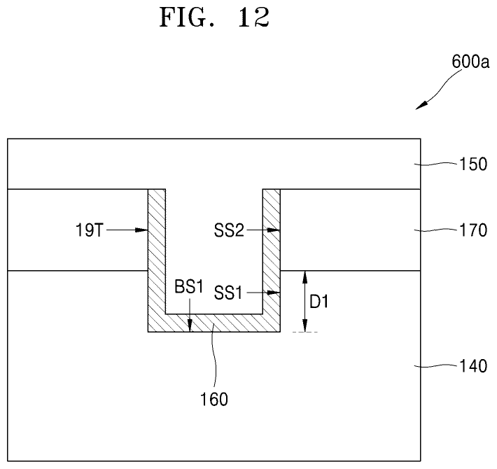

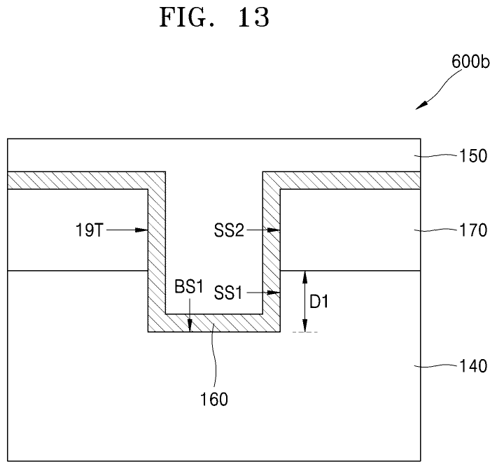

In some embodiments, interconnection layer structures 600a and 600b in FIGS. 12 to 13 may be the same as the interconnection layer structure 600 in FIG. 11 except for the following differences. As shown in the interconnection layer structure 600a of FIG. 12, the work function modulation layer 160 extends between the second side surface SS2 of the first trench 19T and the second interconnection layer 150 within the first trench 19T. As shown in the interconnection layer structure 600b of FIG. 13, the work function modulation layer 160 may extend onto the interlayer insulating layer 170 around the first trench 19T.

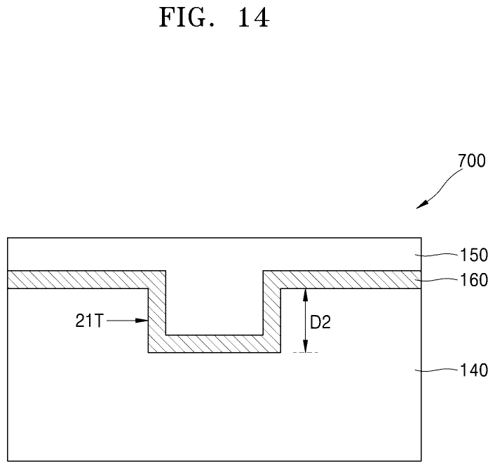

FIG. 14 shows an interconnection layer structure 700 according to an embodiment.

Referring to FIG. 14, a second trench 21T having a second depth D2 is formed in a first interconnection layer 140. A work function modulation layer 160 is formed on an upper surface of the first interconnection layer 140. The work function modulation layer 160 is formed to cover the entire upper surface of the first interconnection layer 140 and entire side and bottom surfaces of the second trench 21T. In the second trench 21T, the work function modulation layer 160 is provided to cover the entire side surface and bottom surface of the second trench 21T, but does not completely fill the second trench 21T. The second trench 21T, the entire side and bottom surfaces of which are covered with the work function modulation layer 160, may be completely filled with the second interconnection layer 150. The second interconnection layer 150 fills the second trench 21T and extends onto the work function modulation layer 160 around the second trench 21T. The work function modulation layer 160 directly contacts the first interconnection layer 140 thereunder and the second interconnection layer 150 thereon. An entire upper surface of the second interconnection layer 150 may be flat.

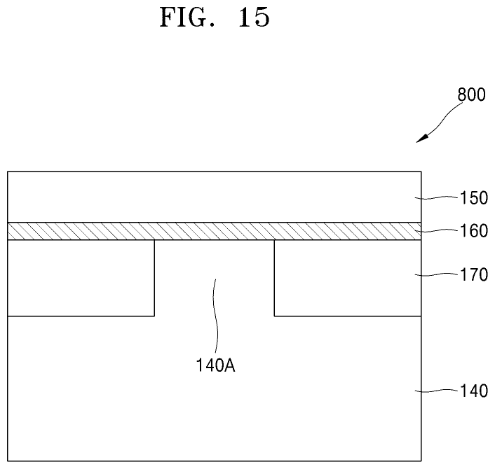

FIG. 15 shows an interconnection layer structure 800 according to an embodiment.

Referring to FIG. 15, the first interconnection layer 140 has a protruding portion 140A protruded upwards. An upper surface around the protruding portion 140A of the first interconnection layer 140 may be flat. A height of an upper surface of the protruding portion 140A of the first interconnection layer 140 is greater than the upper surface around the protruding portion 140A. Accordingly, a step difference is formed between the protruding portion 140A and the upper surface of the first interconnection layer 140 around the protruding portion 140A. The interlayer insulating layer 170 is present on the upper surface of the first interconnection layer 140 around the protruding portion 140A. The interlayer insulating layer 170 may cover the entire upper surface of the first interconnection layer 140 around the protruding portion 140A. The interlayer insulating layer 170 may be provided to surround the protruding portion 140A and contact a side surface of the protruding portion 140A. The interlayer insulating layer 170 may be formed to have the same height as the protruding portion 140A. Accordingly, the upper surface of the interlayer insulating layer 170 and the upper surface of the protruding portion 140A may form surfaces having the same height. The work function modulation layer 160 is provided on the interlayer insulating layer 170 and the protruding portion 140A. The work function modulation layer 160 is provided to cover the entire upper surface of the interlayer insulating layer 170 and the entire upper surface of the protruding portion 140A. The work function modulation layer 160 may be provided to cover at least the entire upper surface of the protruding portion 140A and directly contact the entire upper surface. The work function modulation layer 160 may have a uniform thickness and may be flat overall. The second interconnection layer 150 is formed on the work function modulation layer 160. The second interconnection layer 150 may be formed so that an entire bottom surface of the second interconnection layer 150 is in direct contact with the work function modulation layer 160. An upper surface of the second interconnection layer 150 may be flat.

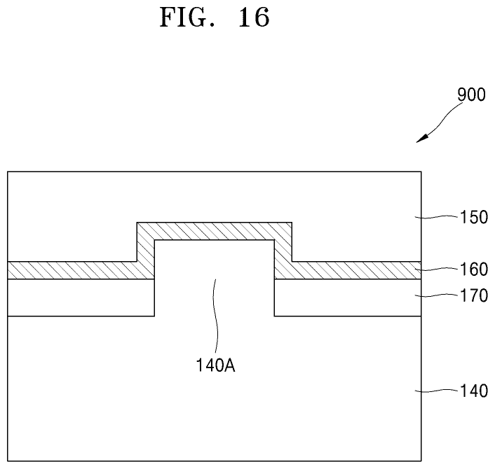

In some embodiments, as shown in the interconnection layer structure 900 of FIG. 16, the interlayer insulating layer 170 may be formed lower than the upper surface of the protruding portion 140A, and thus, a portion of a side surface of the protruding portion 140A may be exposed. An entire exposed portion of the side surface of the protruding portion 140A may be covered with the work function modulation layer 160.

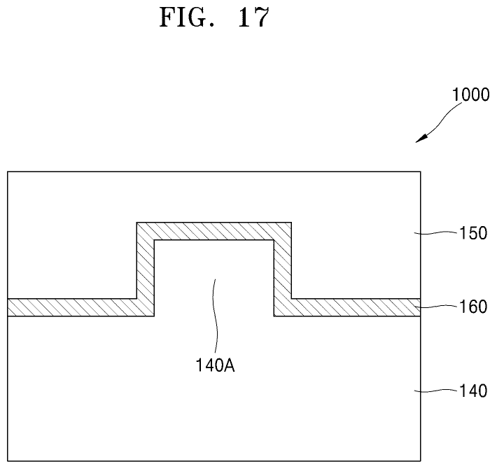

In some embodiments, as shown in FIG. 17, an interconnection layer structure 1000 may be like the interconnection layer structure 800, except the interlayer insulating layer 170 may be omitted.

Referring to the interconnection layer structure 1000 in FIG. 17, the entire side surface and the entire upper surface of the protruding portion 140A of the first interconnection layer 140 are covered with the work function modulation layer 160. That is, the work function modulation layer 160 is provided to directly cover the entire surface of the protruding portion 140A of the first interconnection layer 140 and the entire upper surface of the first interconnection layer 140 around the protruding portion 140A. As a result, the interconnection layer structure 800 in which the interlayer insulating layer 170 is omitted is a layer structure in which the first interconnection layer 140, the work function modulation layer 160, and the second interconnection layer 150 are sequentially stacked, and the work function modulation layer 160 is in direct contact with the first and second interconnection layers 140 and 150. A planar shape of the protruding portion 140A of the first interconnection layer 140 may be circular or non-circular (e.g., elliptical or polygonal), but is not limited thereto.

In some embodiments, although not shown in the drawings, in FIGS. 15 to 17, the first interconnection layer 140 may have a plurality of protruding portions.

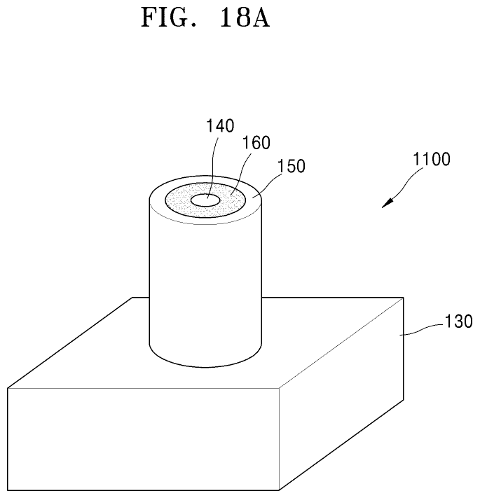

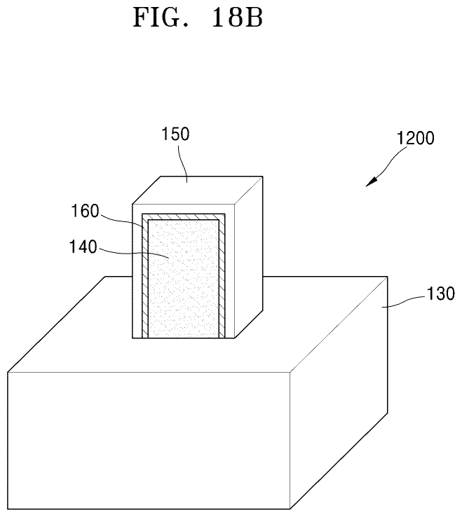

FIG. 18A shows an interconnection layer structure 1100 according to an embodiment.

Referring to FIG. 18A, in the interconnection layer structure 1100, the first interconnection layer 140 may be on the insulating layer 130 and extend in a direction vertical to a surface of the insulating layer 130. The work function modulation layer 160 may be on the insulating layer 130, extend vertical to the surface of the insulating layer 130, and surround a peripheral surface of the first interconnection layer 140. The second interconnection layer 150 may be on the insulating layer 130, extend vertical to the surface of the insulating layer 130, and surround a peripheral surface of the work function modulation layer 160. The work function modulation layer 160 may be between the first interconnection layer 140 and the second interconnection layer 150 and may directly contact at least one of the first interconnection layer 140 and the second interconnection layer 150. The first interconnection layer 140, work function modulation layer 160, and second interconnection layer 150 may be concentrically arranged around each other.

FIG. 18B shows an interconnection layer structure 1200 according to an embodiment.

Referring to FIG. 18B, in the interconnection layer structure 1200, the first interconnection layer 140 may be on the insulating layer 130 and extend in a direction vertical to a surface of the insulating layer 130. The work function modulation layer 160 may be on the insulating layer 130, extend vertical to the surface of the insulating layer 130, cover a top surface of the first interconnection layer 140, and cover side surfaces of the first interconnection layer 140. The second interconnection layer 150 may be on the insulating layer 130, extend vertical to the surface of the insulating layer 130, cover a top surface of the work function modulation layer 160, and cover side surfaces of the work function modulation layer 160. The work function modulation layer 160 may be between the first interconnection layer 140 and the second interconnection layer 150 and may directly contact at least one of the first interconnection layer 140 and the second interconnection layer 150.

Table 1 below shows a simulation result performed to confirm a change in work function of a metal layer when a work function modulation layer is provided (Y) on a surface of the metal layer and when a work function modulation layer is not provided (N) on the surface of the metal layer. In Table 1, the unit (eV) of the work function is omitted.

In the simulation, a gold (Au) layer and a platinum (Pt) layer were used as the metal layer, and an α-RuCl 3 layer was used as the work function modulation layer.

TABLE 1

| | Work | Work |
|---|---|---|
| Metal | function | function |
| layer | N | (Y) |
| Au | 5.10 | 6.12 |
| Pt | 5.61 | 6.06 |

Referring to Table 1, in the case of a gold layer, when the work function modulation layer is not provided on the surface of the gold layer (N), the work function is about 5.10, whereas when the work function modulation layer is provided on the surface of the gold layer (Y), the work function increases to 6.12.

In the case of a platinum layer, when the work function modulation layer is not provided on the surface of the platinum layer (N), the work function is about 5.61, whereas when the work function modulation layer is provided on the surface of the platinum layer (Y), the work function increases to 6.06.

Table 1 suggests that, although the degree of increase in the work function varies depending on the type of metal, the work function of the metal layer increases as the work function modulation layer is provided on the surface of the metal layer.

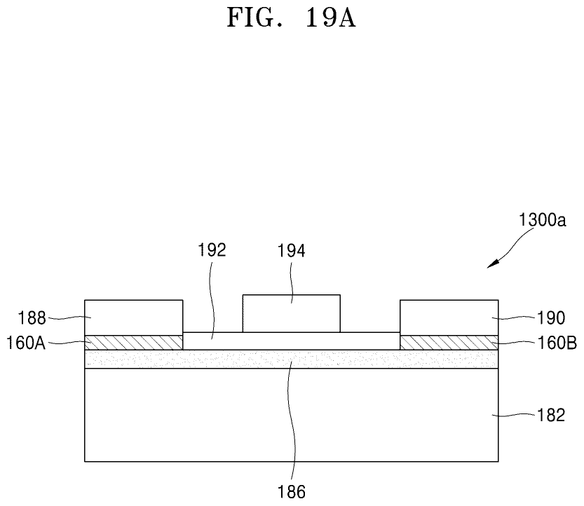

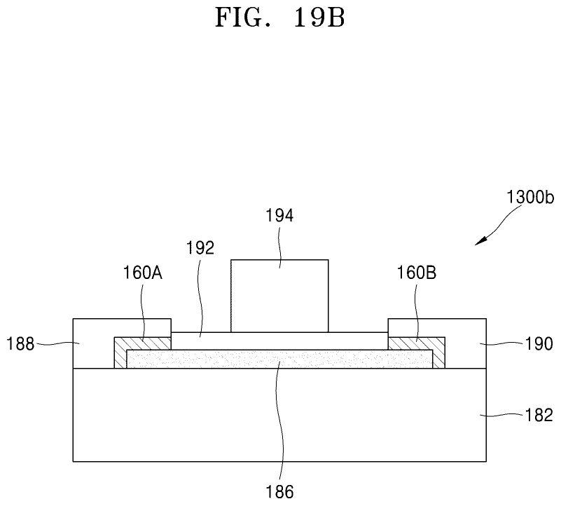

FIG. 19A shows an electronic device 1300a according to an embodiment.

Referring to FIG. 19A, a channel layer 186 is formed on a substrate 182. In some embodiments, the substrate 182 may be an insulating substrate, but is not limited thereto. In some embodiments, the insulating substrate may include metal oxide, parylene-C, an organic material including polyimide, SiO₂, a ceramic material, or a semiconductor such as silicon (Si), but is not limited thereto. In some embodiments, the metal oxide may include aluminum oxide or hafnium oxide, but is not limited thereto. In some embodiments, the aluminum oxide may include Al₂O₃, but is not limited thereto.

In some embodiments, the channel layer 186 may be or include a 2D material layer. In some embodiments, the channel layer 186 may be or include a layer of a 2D semiconductor material. In some embodiments, the 2D semiconductor material layer may include a material having a band gap greater than or equal to a first value. For example, the 2D semiconductor material layer may include TMD, black phosphorus (BP), or Janus type TMD, but is not limited thereto. For example, the 2D semiconductor material layer may include MoS₂, WS₂, MoSe₂, or WSe₂.

In some embodiments, the channel layer 186 may be a monolayer or multi-layer of a 2D semiconductor material. For example, the channel layer 186 may be formed in a layered structure including a few or dozens of 2D monolayers that are stacked. In some embodiments, the layered structure may include about 1 to about 10 or about 1 to about 5 2D semiconductor material monolayers.

First and second electrode layers 188 and 190 are spaced apart from each other on the channel layer 186. A first work function increasing layer 160A is provided between the first electrode layer 188 and the channel layer 186, and a second work function increasing layer 160B is provided between the second electrode layer 190 and the channel layer 186. The first work function increasing layer 160A covers an entire bottom surface of the first electrode layer 188 facing the channel layer 186. The first work function increasing layer 160A directly contacts the channel layer 186 and the first electrode layer 188. The channel layer 186 and the first electrode layer 188 do not directly contact each other, but may indirectly contact each other through the first work function increasing layer 160A.

The second work function increasing layer 160B covers an entire bottom surface of the second electrode layer 190 facing the channel layer 186. The second work function increasing layer 160B directly contacts the channel layer 186 and the second electrode layer 190. The channel layer 186 and the second electrode layer 190 do not directly contact each other, but may indirectly contact each other through the second work function increasing layer 160B.

In some embodiments, the first and second work function increasing layers 160A and 160B may be the work function modulation layer 160 described with reference to FIGS. 1 to 18B or function as the work function modulation layer 160.

One of the first and second electrode layers 188 and 190 may be a source electrode, and the other may be a drain electrode. A gate insulating layer 192 is present on the channel layer 186 between the first and second electrode layers 188 and 190. The gate insulating layer 192 may cover the entire channel layer 186 between the first and second electrode layers 188 and 190, but may be formed only under a third electrode layer 194. The gate insulating layer 192 may include an insulating oxide film or a nitride film, but is not limited thereto. The third electrode layer 194 formed on the gate insulating layer 192 is separated and electrically insulated from the first and second electrode layers 188 and 190. The third electrode layer 194 may be a control electrode that regulates a flow of carriers (e.g., electrons or holes) flowing through the channel layer 186. In some embodiments, the third electrode layer 194 may be a gate electrode.

In some embodiments, the electronic device 1300a may be a field effect transistor (FET). In some embodiments, when the electronic device 1300a is an n-metal oxide semiconductor (MOS) type FET, the work functions of the first and second electrode layers 188 and 190 contacting the first and second work function increasing layers 160A and 160B may be 4 eV or less.

In some embodiments, when the electronic device 1300a is a p-MOS type FET, the work functions of the first and second electrode layers 188 and 190 contacting the first and second work function increasing layers 160A and 160B may be equal to or greater than 5 eV.

In the electronic device 1300a, the channel layer 186, the first and second work function increasing layers 160A and 160B, and the first and second electrode layers 188 and 190 may form a vertically stacked interconnection layer structure described above.

Therefore, in the electronic device 1300a, an ohmic contact may be formed between the first and second electrode layers 188 and 190 and the channel layer 186 by the first and second work function increasing layers 160A and 160B, and accordingly, a current in an on-state of the electronic device 1300a, that is, an on-current may be increased.

FIG. 19B shows an electronic device 1300b according to an embodiment.

Referring to FIG. 19B, the channel layer 186 is formed on a partial region of an upper surface of the substrate 182, and the first and second electrode layers 188 and 190 may be provided on the upper surface of the substrate 182 around the channel layer 186. The first and second electrode layers 188 and 190 may cover side surfaces of the channel layer 186 and may extend over a portion of an upper surface of the channel layer 186. In such a layer structure, the first work function increasing layer 160A is provided between the channel layer 186 and the first electrode layer 188, and the second work function increasing layer 160B is provided between the channel layer 186 and the second electrode layer 190. The first and second work function increasing layers 160A and 160B are in direct contact with the side surface and the upper surface of the channel layer 186, and the first and second electrode layers 188 and 190 respectively are provided on the first and second work function increasing layers 160A and 160B.

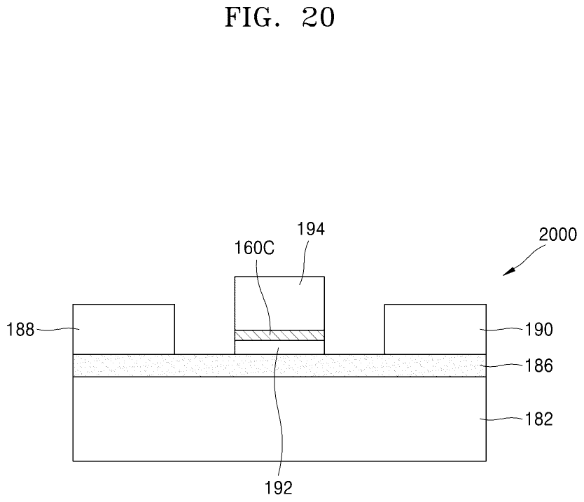

FIG. 20 shows an electronic device 2000 according to an embodiment. Only parts different from the electronic device 1300a are described. The electronic device 2000 may be a field effect transistor.

Referring to FIG. 20, the first and second electrode layers 188 and 190 are separated from each other on the channel layer 186. The first and second electrode layers 188 and 190 directly contact the channel layer 186. A gate insulating layer 192, a third work function increasing layer 160C, and a third electrode layer 194 are sequentially stacked on the channel layer 186 spaced apart from the first and second electrode layers 188 and 190. An entire lower surface of the third electrode layer 194 is covered with the third work function increasing layer 160C and directly contacts the third work function increasing layer 160C. In some embodiments, the third electrode layer 194 may correspond to an interconnection layer that is a metal interconnection layer among the first and second interconnection layers 140 and 150 described above. In some embodiments, the third work function increasing layer 160C may be the work function modulation layer 160 described above or function as the work function modulation layer 160.

As a bottom surface of the third electrode layer 194 is covered with the third work function increasing layer 160C, the work function of the third electrode layer 194 may be increased, and thus, in an operation of the electronic device 2000, a threshold voltage Vth may be different from when the third work function increasing layer 160C is not provided. As an example, the threshold voltage Vth of the electronic device 2000 including the third work function increasing layer 160C may be increased than when the third work function increasing layer 160C is not present.

As such, because the threshold voltage of the electronic device 2000 varies depending on whether the third work function increasing layer 160C is present or not, by using this characteristic, a logic device may be formed by using the electronic device 2000 including the third work function increasing layer 160C together with an electronic device not including the third work function increasing layer 160C.

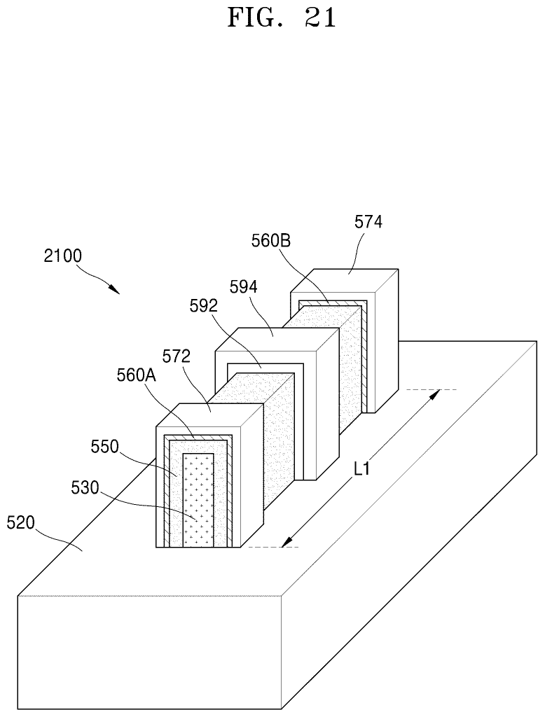

FIG. 21 is a three-dimensional (3D) view of an electronic device 2100 according to an embodiment. The electronic device 2100 may be a fin-type transistor.

Referring to FIG. 21, an insulating layer 530 having a fin-shape formed in a direction perpendicular to a substrate 520 and having a first length L1 in a given direction is present. A material of the substrate 520 may be the same as that of the substrate 182 of the electronic device 1300a. Side and upper surfaces of the insulating layer 530 are covered with a channel layer 550. A material of the channel layer 550 may be the same as that of the channel layer 186 of the electronic device 1300a.

Reference numeral 572 denotes a first electrode layer, and reference numeral 574 denotes a second electrode layer. One of the first and second electrode layers 572 and 574 may be a source electrode, and the other may be a drain electrode. Reference numeral 594 denotes a gate electrode. A first work function increasing layer 560A covering side and upper surfaces of the channel layer 550 is present between the first electrode layer 572 and the channel layer 550, and a second work function increasing layer 560B covering side and upper surfaces of the channel layer 550 is present between the second electrode layer 574 and the channel layer 550. The first and second work function increasing layers 560A and 560B respectively may be the same material layer as the first and second work function increasing layers 160A and 160B described in the electronic device 1300a. The channel layer 550, the first and second work function increasing layers 560A and 560B, and the first and second electrode layers 572 and 574 have a sequentially stacked layer structure, which may correspond to the interconnection layer structures described with reference to FIGS. 1 to 18B. Therefore, an ohmic contact may be formed between the first and second electrode layers 572 and 574 and the channel layer 550.

A gate insulating layer 592 existing between the gate electrode 594 and the channel layer 550 may extend onto the channel layer 550 between the first and second electrode layers 572 and 574 and the gate electrode 594.

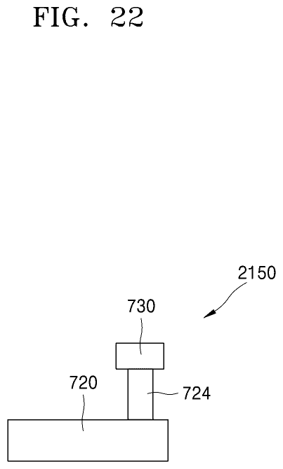

FIG. 22 schematically shows an electronic device 2150 according to an embodiment. The electronic device 2150 may be a memory device.

The electronic device 2150 may include a structure in which a data storage element 730 is connected to a switching device 720 that controls the flow of a current. The switching device 720 and the data storage element 730 may be connected through a conductive layer 724. In some embodiments, the conductive layer 724 may be a conductive plug filling a via hole between the switching device 720 and the data storage element 730. In some embodiments, the switching device 720 may include a field effect transistor. In some embodiments, the switching device 720 may include the electronic device 1300a illustrated in FIG. 19A. When the switching device 720 includes the electronic device 1300a, the conductive layer 724 may be connected to the second electrode layer 190. In some embodiments, the data storage element 730 may include a volatile storage unit in which data disappears when power is turned off or a non-volatile storage unit in which data does not disappear even after power is turned off. In some embodiments, the data storage element 730 may include a capacitor, or may include a magnetoresistive layer or a phase change layer.

Next, electronic apparatus(es) according to an embodiment will be described. The electronic apparatus(es) according to an embodiment may include the any one of electronic devices according to the embodiment described above.

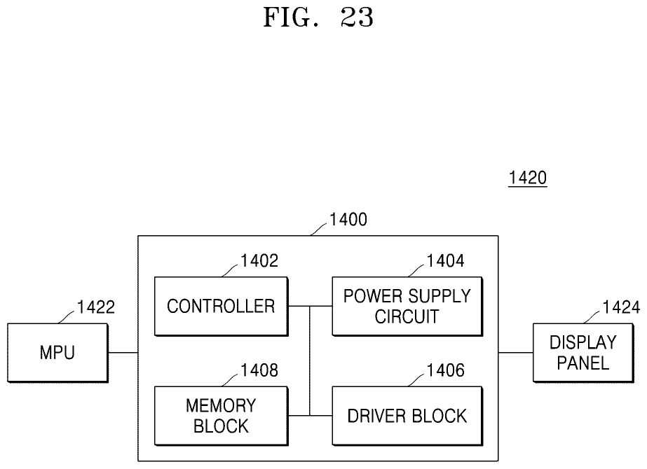

FIG. 23 is a schematic block diagram of a display driver IC (DDI) 1400 and a display device 1420 including the DDI 1400 according to an embodiment.

Referring to FIG. 23, the DDI 1400 may include a controller 1402, a power supply circuit unit 1404, a driver block 1406, and a memory block 1408. The controller 1402 receives and decodes a command from a main processing unit (MPU) 1422 and controls each block of the DDI 1400 to implement an operation according to the command. The power supply circuit unit 1404 generates a driving voltage in response to the control of the controller 1402. The driver block 1406 drives a display panel 1424 using a driving voltage generated by the power supply circuit unit 1404 in response to the control of the controller 1402. For example, the display panel 1424 may include a liquid crystal display panel, a plasma display panel, an LED panel, an OLED panel, or a micro-LED display panel, but is not limited thereto. The memory block 1408 is a block that temporarily stores a command input to the controller 1402 or control signals output from the controller 1402 or stores necessary data, and includes a volatile memory (e.g., RAM) and/or a non-volatile memory. In some embodiments, the controller 1402 may include an electronic device according to an embodiment described above (e.g., the electronic device 2150 of FIG. 22). In some embodiments, the units and/or blocks included in the DDI 1400 may include a switching device, and the switching device may include one of the electronic devices 1300a, 1300b, 2000 and 2100 shown in FIGS. 19A to 21.

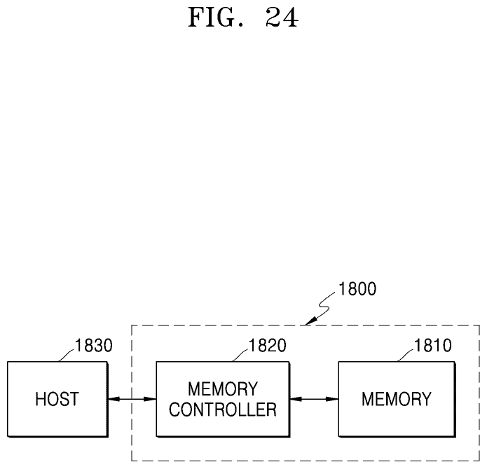

FIG. 24 is a block diagram illustrating an electronic system 1800 according to an embodiment.

Referring to FIG. 24, the electronic system 1800 includes a memory 1810 and a memory controller 1820. The memory controller 1820 may control the memory 1810 to read data from and/or write data to the memory 1810 in response to a request from the host 1830.

In some embodiments, the memory 1810 may include an electronic device according to the embodiment described above (e.g., the electronic device 2150 of FIG. 22). In some embodiments, the memory 1810 and the memory controller 1820 of the electronic system 1800 may include a switching device, and the switching device may include one of the 1300a, 1300b, 2000 and 2100 shown in FIGS. 19A to 21.

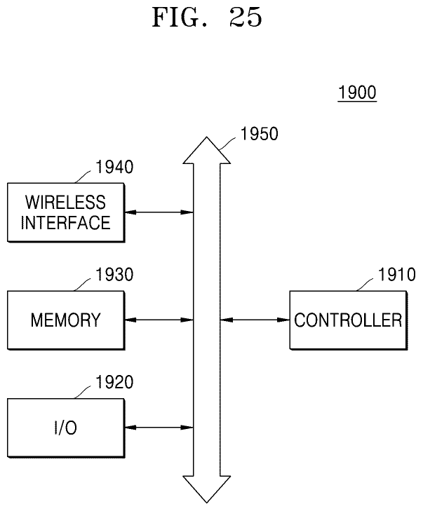

FIG. 25 is a block diagram of an electronic system 1900 according to an embodiment.

Referring to FIG. 25, the electronic system 1900 may configure a wireless communication device or a device capable of transmitting and/or receiving information in a wireless environment. The electronic system 1900 includes a controller 1910, an input/output device 1920, a memory 1930, and a wireless interface 1940, and these components are interconnected to each other through a bus 1950.

The controller 1910 may include at least one of a microprocessor, a digital signal processor, and a processing device similar thereto. The input/output device 1920 may include at least one of a keypad, a keyboard, and a display.

The memory 1930 may be used to store instructions executed by the controller 1910. For example, the memory 1930 may be used to store user data. In some embodiments, the memory 1930 may include an electronic device according to the embodiment described above (e.g., the electronic device 2150 of FIG. 22).

In some embodiments, the components, that is, the controller 1910, the input/output device 1920, the memory 1930, and wireless interface 1940, included in the electronic system 1900 may include a switching device, and the switching device may include one of the electronic devices 1300a, 1300b, 2000 and 2100 shown in FIGS. 19A to 21.

The electronic system 1900 may use the wireless interface 1940 to transmit/receive data over a wireless communication network. The wireless interface 1940 may include an antenna and/or a wireless transceiver. In some embodiments, the electronic system 1900 may be used in a communication interface protocol of a third-generation communication system, for example, code division multiple access (CDMA), global system for mobile communications (GSM), north American digital cellular (NADC), extended-time division multiple access (E-TDMA), and/or wide band code division multiple access (WCDMA), but is not limited thereto.

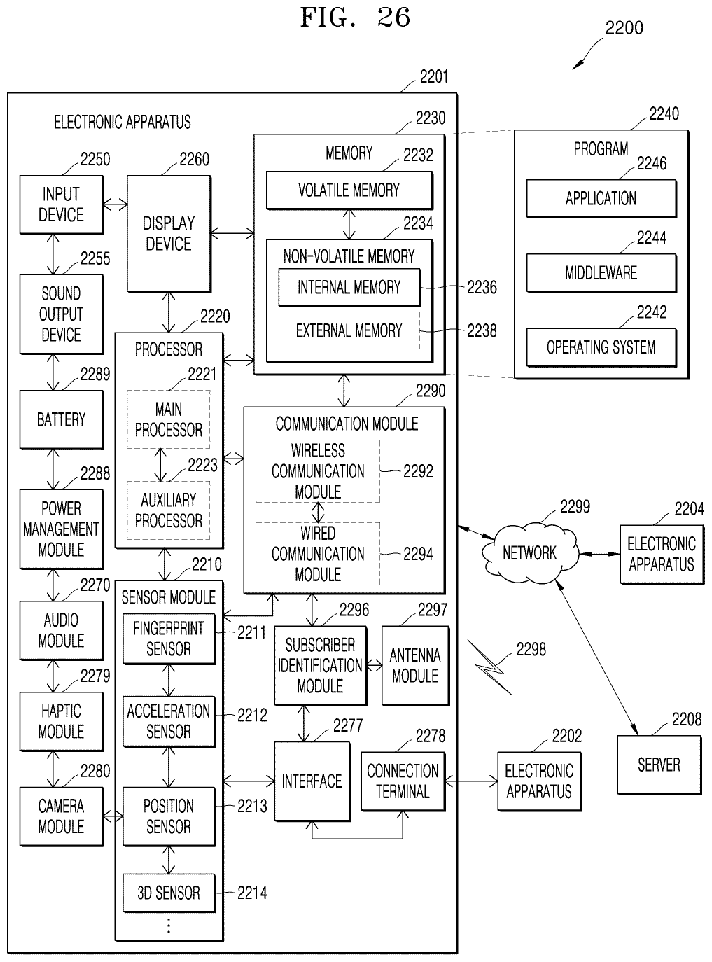

FIG. 26 is a block diagram showing a schematic configuration of an electronic apparatus according to an embodiment.

Referring to FIG. 26, in a network environment 2200, an electronic apparatus 2201 may communicate with another electronic apparatus 2202 through a first network 2298 (a short-range wireless communication network, etc.) or may communicate with another electronic apparatus 2204 and/or a server 2208 through a second network 2299 (a remote wireless communication network). The electronic apparatus 2201 may communicate with the electronic apparatus 2204 through the server 2208. The electronic apparatus 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297. In the electronic apparatus 2201, some of these components (e.g., the display device 2260) may be omitted or other components may be added. Some of these components may be implemented as one integrated circuit. For example, a fingerprint sensor 2211 of the sensor module 2210, an iris sensor, an illuminance sensor, etc. may be implemented in a form embedded in the display device 2260 (a display, etc.).

The processor 2220 may execute software (such as a program 2240) to control one or a plurality of other components (hardware, software components, etc.) of the electronic apparatus 2201 connected to the processor 2220, and may perform various data processing or operations. As part of data processing or operations, the processor 2220 may load commands and/or data received from other components (the sensor module 2210, the communication module 2290, etc.) into a volatile memory 2232, and may process commands and/or data stored in the volatile memory 2232, and store resulting data in a non-volatile memory 2234. The processor 2220 may include a main processor 2221 (a central processing unit, an application processor, etc.) and an auxiliary processor 2223 (a graphics processing unit, an image signal processor, a sensor hub processor, a communication processor, etc.) that may be operated independently or together with the main processor 2221. The auxiliary processor 2223 may use less power than the main processor 2221 and may perform a specialized function.

The auxiliary processor 2223 may control functions and/or states related to some of the components (e.g., the display device 2260, the sensor module 2210, the communication module 2290) of the electronic apparatus 2201 instead of the main processor 2221 while the main processor 2221 is in an inactive state (sleep state), or together with the main processor 2221 while the main processor 2221 is in an active state (application execution state). The auxiliary processor 2223 (an image signal processor, a communication processor, etc.) may be implemented as a part of other functionally related components (the camera module 2280, the communication module 2290, etc.).

The memory 2230 may store various data required by components of the electronic apparatus 2201 (the processor 2220, the sensor module 2276, etc.). The data may include, for example, input data and/or output data for software (such as the program 2240) and commands related to the software. The memory 2230 may include a volatile memory 2232 and/or a non-volatile memory 2234. The non-volatile memory 2234 may include an internal memory 2236 and an external memory 2238. In some embodiments, the memory 2230 may include an electronic device according to an embodiment described above (e.g., the electronic device 2150 of FIG. 22).

The program 2240 may be stored as software in the memory 2230, and may include an operating system 2242, middleware 2244, and/or an application 2246.

The input device 2250 may receive commands and/or data to be used in a component (e.g., the processor 2220) of the electronic apparatus 2201 from the outside of the electronic apparatus 2201 (e.g., a user). The input device 2250 may include a microphone, a mouse, a keyboard, and/or a digital pen (such as a stylus pen).

The sound output device 2255 may output a sound signal to the outside of the electronic device 2201. The sound output device 2255 may include a speaker and/or a receiver. The speaker may be used for general purposes, such as multimedia playback or recording playback, and the receiver may be used to receive incoming calls. The receiver may be integrated as a part of the speaker or may be implemented as an independent separate device.

The display device 2260 may visually provide information to the outside of the electronic device 2201. The display device 2260 may include a control circuit for controlling a display, a hologram device, or a projector and a corresponding device. The display device 2260 may include a touch circuitry configured to sense a touch, and/or a sensor circuitry configured to measure the intensity of force generated by the touch (e.g., a pressure sensor, etc.).

The audio module 2270 may convert a sound into an electric signal or, conversely, convert an electric signal into a sound. The audio module 2270 may obtain a sound through the input device 2250 or may output a sound through a speaker and/or headphone of the sound output device 2255 and/or another electronic apparatus (e.g., the electronic apparatus 2202) directly or wirelessly connected to electronic apparatus 2201.

The sensor module 2210 may detect an operating state (power, temperature, etc.) of the electronic apparatus 2201 or an external environmental state (user state, etc.), and may generate an electrical signal and/or data value corresponding to the sensed state. The sensor module 2210 may include a fingerprint sensor 2211, an acceleration sensor 2212, a position sensor 2213, a 3D sensor 2214, and the like, and in addition to the above sensors, may include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, and/or an illuminance sensor.

The 3D sensor 2214 may sense a shape and movement of an object by irradiating a desired and/or alternatively predetermined light to the object and analyzing light reflected from the object, and may include a meta-optical device.

The interface 2277 may support one or more designated protocols that may be used by the electronic apparatus 2201 to connect directly or wirelessly with another electronic apparatus (e.g., the electronic device 2102). The interface 2277 may include a high-definition multimedia interface (HDMI), a universal serial bus (USB) interface, an SD card interface, and/or an audio interface.

The connection terminal 2278 may include a connector through which the electronic apparatus 2201 may be physically connected to another electronic apparatus (e.g., the electronic apparatus 2202). The connection terminal 2278 may include an HDMI connector, a USB connector, an SD card connector, and/or an audio connector (e.g., a headphone connector).

The haptic module 2279 may convert an electrical signal into a mechanical stimulus (vibration, movement, etc.) or an electrical stimulus that the user may perceive through tactile or kinesthetic sense. The haptic module 2279 may include a motor, a piezoelectric element, and/or an electrical stimulation device.

The camera module 2280 may capture still images and moving images. The camera module 2280 may include a lens assembly including one or more lenses, image sensors, image signal processors, and/or flashes. The lens assembly included in the camera module 2280 may collect light emitted from an object, which is an imaging target.

The power management module 2288 may manage power supplied to the electronic apparatus 2201. The power management module 2288 may be implemented as part of a power management integrated circuit (PMIC).

The battery 2289 may supply power to components of the electronic apparatus 2201. The battery 2289 may include a non-rechargeable primary cell, a rechargeable secondary cell, and/or a fuel cell.

The communication module 2290 establishes a direct (wired) communication channel and/or wireless communication channel between the electronic apparatus 2201 and other electronic apparatuses (the electronic apparatus 2202, an electronic apparatus 2204, server 2208, etc.) and performing communication through an established communication channel. The communication module 2290 may include one or more communication processors that operate independently of the processor 2220 (e.g., an application processor) and support direct communication and/or wireless communication. The communication module 2290 may include a wireless communication module 2292 (a cellular communication module, a short-range wireless communication module, a global navigation satellite system (GNSS, etc.) communication module) and/or a wired communication module 2294 (a local area network (LAN) communication module, or a power line communication module, etc.). Among these communication modules, a corresponding communication module may communicate with other electronic apparatuses through the first network 2298 (a short-range communication network, such as Bluetooth, WiFi Direct, or infrared data association (IrDA)) or the second network 2299 (a telecommunication network, such as a cellular network, the Internet, or a computer network (LAN) and WAN, etc.). The various types of communication modules may be integrated into one component (a single chip, etc.) or implemented as a plurality of components (plural chips) separate from each other. The wireless communication module 2292 may identify and authenticate the electronic apparatus 2201 within a communication network, such as the first network 2298 and/or the second network 2299 by using subscriber information (such as, international mobile subscriber identifier (IMSI)) stored in a subscriber identification module 2296.

The antenna module 2297 may transmit or receive signals and/or power to and from the outside (other electronic apparatuses, etc.). The antenna may include a radiator having a conductive pattern formed on a substrate (PCB, etc.). The antenna module 2297 may include one or a plurality of antennas. When a plurality of antennas is included in the antenna module 2297, an antenna suitable for a communication method used in a communication network, such as the first network 2298 and/or the second network 2299 from among the plurality of antennas may be selected by the communication module 2290. Signals and/or power may be transmitted or received between the communication module 2290 and another electronic apparatus through the selected antenna. In addition to the antenna, other components (an RFIC, etc.) may be included as a part of the antenna module 2297.

Some of the components are connected to each other through a communication method between peripheral devices (a bus, a general purpose input and output (GPIO), a serial peripheral interface (SPI), a mobile industry processor interface (MIPI), etc.), and may interchange signals (commands, data, etc.).

The command or data may be transmitted or received between the electronic apparatus 2201 and the external electronic apparatus 2204 through the server 2208 connected to the second network 2299. The other electronic apparatuses 2202 and 2204 may be the same or different types of electronic apparatus 2201. All or some of operations performed in the electronic apparatus 2201 may be performed in one or more of the other electronic apparatuses 2202, 2204, and 2208. For example, when the electronic apparatus 2201 needs to perform a function or service, the electronic apparatus 2201 may request one or more other electronic apparatuses to perform part or all function or service instead of executing the function or service itself. One or more other electronic apparatuses receiving the request may execute an additional function or service related to the request, and transmit a result of the execution to the electronic apparatus 2201. For this purpose, cloud computing, distributed computing, and/or client-server computing technologies may be used.

In the network environment 2200, at least the electronic apparatus 2201 may include a switching device (e.g., a transistor), and the switching device may include one of the electronic devices 1300a, 1300b, 2000 and 2100 shown in FIGS. 19A to 21. The memory 2230 may include an electronic device according to an embodiment described above (e.g., the electronic device 2150 in FIG. 22).

The interconnection layer structure using the disclosed 2D material includes a metal layer and a semiconductor layer, and a work function modulation layer (work function increasing layer) of a stable 2D material is provided between a contact interface of the metal layer and the semiconductor layer. The work function modulation layer is provided to cover an entire interface of the metal layer in contact with the semiconductor layer and to directly contact the entire interface. Due to the work function modulation layer, the work function of the metal layer is increased and the Schottky barrier between the metal layer and the semiconductor layer is lowered, thereby forming an ohmic contact between the metal layer and the semiconductor layer.

Accordingly, in the case of a field effect transistor (e.g., a p-MOSFET) to which the interconnection layer structure is applied, ON-current may be increased.

Also, a threshold voltage Vth when the interconnection layer structure is applied to a gate of the field effect transistor is different from a threshold voltage when the interconnection layer structure is not applied to the gate. Accordingly, a logic device may be formed by using both a transistor to which the interconnection layer structure is applied to a gate and a transistor to which the interconnection layer structure is not applied.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An interconnection layer structure comprising:
a first interconnection layer; and
a work function modulation layer directly on one surface of the first interconnection layer, wherein
the first interconnection layer includes a metal layer, and
the work function modulation layer is a two-dimensional (2D) material layer that includes ruthenium (Ru).

2. The interconnection layer structure of claim 1, further comprising:
a second interconnection layer facing the first interconnection layer with the work function modulation layer therebetween, wherein
the second interconnection layer directly contacts the work function modulation layer.

3. The interconnection layer structure of claim 2, wherein the second interconnection layer includes a semiconductor layer.

4. The interconnection layer structure of claim 2, further comprising:
an insulating layer, wherein
the first interconnection layer, the work function modulation layer, and the second interconnection layer are stacked in a horizontal direction on one surface of the insulating layer.

5. The interconnection layer structure of claim 4, wherein a portion of the first interconnection layer and the second interconnection layer overlap each other.

6. The interconnection layer structure of claim 2, further comprising:
an insulating layer, wherein
the first interconnection layer, the work function modulation layer, and the second interconnection layer are vertically stacked on the insulating layer.

7. The interconnection layer structure of claim 6, wherein
one of the first interconnection layer and the second interconnection layer includes a trench,
the work function modulation layer covers a side surface of the trench and a bottom surface of the trench, and
a rest of the trench is filled with an other of the first interconnection layer and the second interconnection layer.

8. The interconnection layer structure of claim 7, further comprising:
an interlayer insulating layer between the first interconnection layer and the second interconnection layer,
wherein the interlayer insulating layer includes a through hole in communication with the trench.

9. The interconnection layer structure of claim 8, wherein the work function modulation layer extends onto the interlayer insulating layer around the trench.

10. The interconnection layer structure of claim 6, wherein
one of the first interconnection layer and the second interconnection layer includes a protruding portion,
the work function modulation layer covers the protruding portion, and
an other of the first interconnection layer and the second interconnection layer covers the protruding portion with the work function modulation layer therebetween.

11. The interconnection layer structure of claim 10, further comprising:
an interlayer insulating layer between the first interconnection layer and the second interconnection layer, wherein
the interlayer insulating layer surrounds the protruding portion.

12. The interconnection layer structure of claim 11, wherein the work function modulation layer extends onto the interlayer insulating layer around the protruding portion.

13. The interconnection layer structure of claim 1, wherein
the first interconnection layer includes a trench, and
the work function modulation layer is in the trench.

14. The interconnection layer structure of claim 1, wherein
the first interconnection layer includes a protruding portion, and
the protruding portion is covered with the work function modulation layer.

15. The interconnection layer structure of claim 1, wherein the work function modulation layer includes ruthenium chloride.

16. The interconnection layer structure of claim 15, wherein the ruthenium chloride includes alpha-phase RuCl3 (α-RuCl3).

17. An electronic device comprising:
a substrate;
a 2D semiconductor channel layer on the substrate;
a first electrode layer connected to a first side region of the 2D semiconductor channel layer;
a second electrode layer connected to a second side region of the 2D semiconductor channel layer and spaced apart from the first electrode layer;
a third electrode layer on the 2D semiconductor channel layer, the third electrode layer being spaced apart from the first electrode layer and the second electrode layer; and
a first work function modulation layer between the 2D semiconductor channel layer and each of the first electrode layer and the second electrode layer, wherein
the first work function modulation layer directly contacts the first electrode layer,
the first work function modulation layer directly contacts the second electrode layer, and
the first work function modulation layer includes ruthenium (Ru).

18. The electronic device of claim 17, further comprising:
a second work function modulation layer directly contacting the third electrode layer between the third electrode layer and the 2D semiconductor channel layer.

19. A memory device comprising:
a switching device; and
a data storage element coupled to the switching device,
wherein the switching device includes the electronic device of claim 17.

20. An electronic apparatus comprising:
the electronic device of claim 17.
